(19) United States
(12) Patent Application Publication
(10) Pub. No.: US 2021/0376117 A1
(43) Pub. Date: Dec. 2, 2021

(54) METHOD FOR MANUFACTURING AN IGBT DEVICE

(71) Applicant: Shaghai Huahong Grace Semiconductor Manufacturing Corporation, Shaghai (CN)

(72) Inventors: Jia PAN, Shanghai (CN); Jiye YANG, Shanghai (CN); Junjun XING, Shanghai (CN); Xuan HUANG, Shanghai (CN)

(73) Assignee: Shanghai Huahong Grace Semiconductor Manufacturing Corporation, Shanghai (CN)

(21) Appl. No.: 17/018,484

(22) Filed: Sep. 11, 2020

(30) Foreign Application Priority Data
May 29, 2020 (CN) 202010475716.2

(51) Int. Cl. H01L 29/66; H01L 21/288

(52) U.S. Cl. CPC H01L 29/66325; H01L 21/288

(57) ABSTRACT

A method for manufacturing an IGBT device includes: forming a cell structure of the IGBT device in a substrate; forming front metal layers on the substrate; thinning the substrate; forming a collector region on the back of the substrate; forming back metal layers on the back of the substrate; and forming target metal on the front and back of the substrate via electroless plating processes.

### CROSS-REFERENCES TO RELATED APPLICATION

This application claims the priority to Chinese patent application No. CN 202010475716.2 filed at CNIPA on May 29, 2020, and entitled “METHOD FOR MANUFACTURING AN IGBT DEVICE”, the disclosure of which is incorporated herein by reference in entirety.

### TECHNICAL FIELD

The application relates to the field of semiconductor manufacturing, and in particular to a method for manufacturing an IGBT device.

### BACKGROUND

Insulated Gate Bipolar Transistor (IGBT) devices are core devices of new energy power electronic products. With the more extensive promotion in recent years, the products in which IGBT devices are used not only include traditional products such as white goods, industrial frequency converters and welding machines, but also include high-end products such as new energy vehicles.

At present, IGBT is developing towards the direction of high voltage and high current. The chip technology and packaging of IGBT are facing new challenges. For high-current IGBT chips and modules, the heat dissipation of the entire module has become a research focus. When an IGBT chip is packaged, the material for wire bonding has developed from the aluminum wire bonding to the ribbon bonding of copper. Therefore, the requirements on the thickness and hardness of the front metal of the IGBT become higher.

### BRIEF SUMMARY

According to some embodiments in this application, a method for manufacturing an IGBT device is disclosed in the following steps: forming a cell structure of the IGBT device in a substrate; forming front metal layers on the substrate; thinning the substrate; forming a collector region on the back of the substrate; forming back metal layers on the back of the substrate; and forming target metal on the front and back of the substrate via electroless plating processes.

### BRIEF DESCRIPTION OF THE DRAWINGS

FIG. 1 is a flowchart of a method for manufacturing an IGBT device, according to one embodiment of the present application.

FIG. 2 shows the device cross sectional in a manufacturing process of an IGBT device.

FIG. 3 is a device cross sectional in a manufacturing process of an IGBT device.

FIG. 4 is a device cross sectional in a manufacturing process of an IGBT device.

FIG. 5 shows the device cross sectional view after the target metal is formed on the device, according to one embodiment of the present application.

Reference numbers in the drawings are listed in the following:
11: substrate; 12: front metal layer; 13: dielectric layer; 14: back metal layer; 15: target metal.

### DETAILED DESCRIPTION

The technical solutions in this application will be clearly and completely described below with reference to the drawings. Obviously, the described embodiments are part of the embodiments of the application, instead of all them. Based on the embodiments in the present application, all other embodiments obtained by one skilled in the art without contributing any inventive labor shall fall into the protection scope of the present application.

In the description of this application, it should be noted that the orientation or positional relationship indicated by the terms “center”, “upper”, “lower”, “left”, “right”, “vertical”, “horizontal”, “inside”, “outside”, or the like is based on the orientation or positional relationship shown in the drawings, is only for the convenience of describing this application and simplified description, and does not indicate or imply that the indicated device or element must have a specific orientation or be configured and operated in a specific orientation. Therefore, the orientation or positional relationship should not to be construed as limitations on the present application. In addition, the terms “first,” “second,” and “third” are used for descriptive purposes only and should not be construed to indicate or imply relative importance.

In the description of this application, it should be noted that the terms “installation”, “connected”, and “connection” should be understood in a broad sense, unless explicitly stated and defined otherwise, for example, they may be fixed connection or removable connection, or integral connection; can be mechanical or electrical connection; can be direct connection, or indirect connection through an intermediate medium, or the internal communication of two elements, and can be wireless or wired connection. For those of ordinary skill in the art, the specific meanings of the above terms in this application can be understood in specific situations.

In addition, the technical features involved in the different implementations of the present application described below can be combined with each other as long as they do not conflict with each other.

Since the requirement on heat dissipation of the IGBT device becomes increasingly high, the thickness of the front metal of the IGBT device increases. However, with the increase of the thickness of the front metal, the overall stress of the wafer also increases, which will cause the deformation of the wafer. Wafer deformation will increase the difficulty of subsequent manufacturing processes, such as packaging, and even lead to wafer fracture in serious situations.

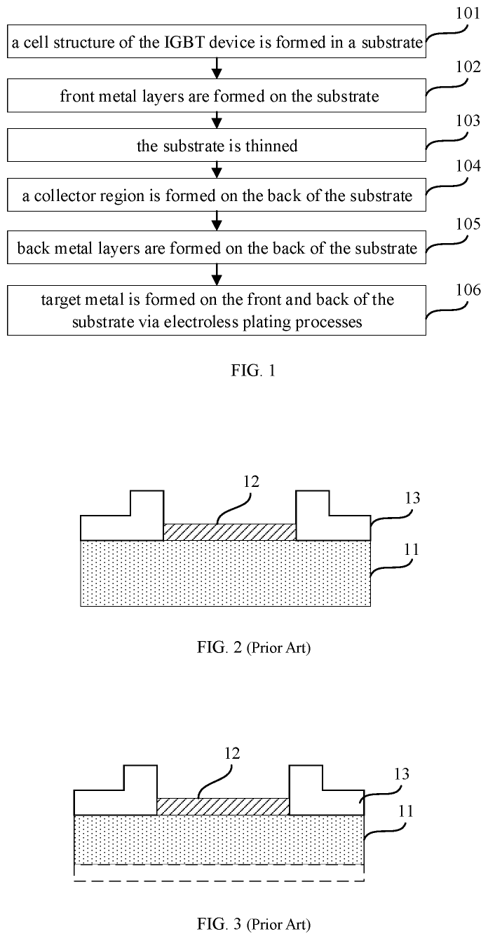

In order to solve the problem that the wafer is easy to fracture due to the increase of the thickness of the front metal of the wafer, the embodiment of the present application provides a method for manufacturing an IGBT device, including the following steps illustrated in FIG. 1.

In step 101, a cell structure of the IGBT device is formed in a substrate.

The cell structure of the IGBT device includes a drift region, a body region, a source region, a gate structure and a collector region.

In step 102, front metal layers are formed on the substrate.

FIG. 2 illustrates the device cross sectional in a manufacturing process of an IGBT device. Dielectric layer 13 is formed on a substrate 11, and front metal layers 12 are formed on the substrate 11.

In step 103, the substrate is thinned.

FIG. 3 illustrates the device cross sectional after the substrate is thinned. The substrate 11 is thinned from the back, and the thickness of the substrate 11 is reduced.

In one embodiment, thinning is performed via TAIKO processes.

In step 104, a collector region is formed on the back of the substrate.

The collector region in the back of the thinned substrate is formed, via ion implantation and anneal.

In step 105, back metal layers are formed on the back of the substrate.

Metal is deposited on the back of the substrate to form the back metal layers.

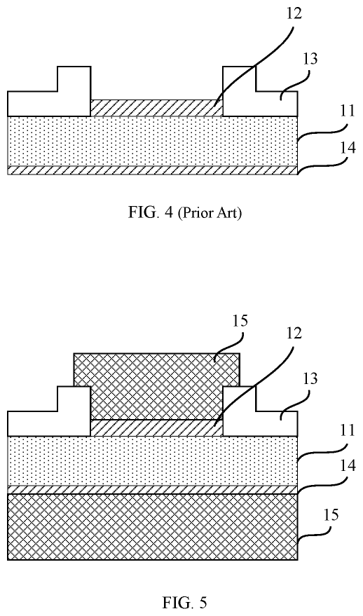

FIG. 4 illustrates a device cross sectional after metal is deposited on the back of the substrate, back metal layers 14 are formed on the back of the substrate 11.

In step 106, target metal is formed on the front and back of the substrate via electroless plating processes.

The wafer is entirely put into a reaction tank for the electroless plating processes, the front surface and back surface of the wafer are immersed in reaction solution, and the front metal layer and back metal layer of the substrate are plated with the target metal at the same time.

The target metal is a layer of metal, or the target metal consists of a plurality of layers of metal, the material and thickness of each layer of metal are determined according to the actual situation.

FIG. 5 illustrates the device cross sectional view after the target metal is formed on the device, according to one embodiment of the present application.

The front metal layer 12 on the front of the substrate 11 is plated with the target metal 15, and the back metal layer 14 on the back of the substrate 11 is plated with the target metal 15.

In summary, by forming the target metal on the front and back of the substrate via electroless plating processes, the problem that the wafer with thicker front metal layer easily caused to be deformed has been overcome.

The benefit of this technique includes optimizing the overall stress of the wafer and improving the packaging performance.

In some embodiments, forming the target metal on the front and back of the substrate via electroless plating processes, i.e., the step 106, may be implemented in the following steps:

Predetermined layers of target metal are formed on the surface of the front metal layers and the back metal layers, via electroless plating processes.

Since the wafer is entirely immersed in reaction solution for electroless plating processes, each layer of target metal on the front metal layer and the back metal layer is formed at the same time.

In some embodiments, the number of predetermined layers is two, and the target metal is sequentially nickel (Ni) and gold (Au). Firstly, the electroless plating process is used to plate nickel on the front metal layer and the back metal layer of the substrate, and then the electroless plating process is used to plate gold on the nickel layer on the front surface and back surface of the substrate.

In some embodiments, the number of predetermined layers is three, and the target metal is sequentially nickel (Ni), palladium (Pd), and gold (Au). Firstly, the electroless plating process is used to plate nickel on the front metal layer and the back metal layer of the substrate, and then the electroless plating process is used to plate palladium on the nickel layer on the front surface and back surface of the substrate, and finally the electroless plating process is used to plate gold on the palladium layer on the front surface and back surface of the substrate.

The thickness of each layer of metal in the target metal layer depends on the welding and packaging conditions of the device. For example, the thickness range of nickel is 0.5-20 um; the thickness range of gold is 500-5000 Å; the thickness range of palladium is 500-5000 Å.

In one example, nickel, palladium and gold are plated on the front surface of the substrate of the cell structure of the IGBT device via electroless plating processes. The thickness of nickel is 1.0 um, the thickness of palladium is 0.1 um, the thickness of gold is 0.05 um, and the deformation of the wafer is 0.335 mm in the x-axis direction and 0.363 mm in the y-axis direction.

In another example, by performing the method of for manufacturing the IGBT device provided in the embodiment of the present application, nickel, palladium and gold are plated on the front surface and back surface of the substrate via electroless plating processes. The thickness of nickel is 12.0 um, the thickness of palladium is 0.1 um, the thickness of gold is 0.05 um, and the deformation of the wafer is 0.426 mm in the x-axis direction and 0.387 mm in the y-axis direction.

According to the above two examples, it can be seen that by performing the method for manufacturing the IGBT device provided in the embodiment of the present application, even if the thickness of nickel in the front metal is greatly increased, the deformation of the wafer can be controlled within a small range and the overall stress of the wafer can be optimized.

In some embodiments, forming the cell structure of the IGBT in the substrate, i.e., step 101, may be implemented in the following steps:

In step 1011, a drift region is formed in the substrate.

An epitaxial layer is formed on the substrate, and a drift region is formed in the epitaxial layer via the ion implantation process.

In some embodiments, the substrate is a P-type substrate, and an N-drift region is formed by implanting phosphorus ions.

In step 1012, the body region is formed in the drift region.

In one example, boron ions are implanted into a predetermined region in the drift region via the ion implantation process to form a P-type body region.

In step 1013, a gate structure of the IGBT device is formed.

The gate structure of the IGBT device is a polysilicon gate on the surface of substrate, or a trench gate in the substrate.

In one example, the gate structure is a polysilicon gate on the surface of the substrate. A gate oxide layer is formed on the surface of the substrate, a polysilicon layer is deposited on the gate oxide layer, and the polysilicon layer is etched by photolithography and etching processes to form the polysilicon gate.

In another example, the gate structure is a trench gate. A trench is formed in the substrate by photolithography and etching processes. The bottom of the trench is located in the drift region, a gate oxide layer covering the bottom and sidewalls of the trench is formed, and the trench is filled with polysilicon to form the trench gate.

In step 1014, the source region is formed in the body region.

In some examples, boron ions are implanted into a predetermined region in the body region via the ion implantation process to form the source region.

In some embodiments, forming the front metal layer on the substrate, i.e., step 102, can be implemented in the following steps:

In step 1021, the interlayer dielectric layer is deposited on the substrate.

In step 1022, contacts are formed in the interlayer dielectric layer via phlithography and etching processes.

The source region and the gate of the IGBT are connected the contacts.

In step 1023, the front metal layer is formed on the surface of the interlayer dielectric layer.

Alternatively, metal is sputtered on the surface of the interlayer dielectric layer, the unnecessary metal is etched to be removed, and the metal electrode includes the gate and the emitter of the IGBT device.

In some embodiments, the substrate of the IGBT device is a P-type substrate, and N-type epitaxy is formed on the substrate, the drift region is N-type, the body region is P-type, and the source region is N-type.

Obviously, the foregoing embodiments are merely for clear description of made examples, and are not limitations on the implementations. For those of ordinary skill in the art, other different forms of changes or modifications can be made on the basis of the above description. There is no need and cannot be exhaustive for all implementations. And, the obvious changes or modifications introduced thereby are still within the protection scope of this application.

1. A method for manufacturing an IGBT device, comprising:
forming a cell structure of the IGBT device in a substrate;
forming front metal layers on the substrate;
thinning the substrate;
forming a collector region on the back of the substrate;
forming back metal layers on the back of the substrate; and
sequentially forming nickel, palladium and gold on the front and back of the substrate via electroless plating processes;
wherein a thickness range of nickel is 0.5-20 um, a thickness range of gold is 1000-5000 Å, a thickness range of palladium is 500-5000 Å.

2. The method for manufacturing an IGBT device, according to claim 1, wherein the step of forming the cell structure of the IGBT device in a substrate, further comprising:
forming a drift region in the substrate;
forming a body region in the drift region;
forming a gate structure; and
forming source regions in the body region.

3. The method for manufacturing an IGBT device, according to claim 1, wherein the step of forming front metal layers on the surface, further comprising:
depositing interlayer dielectric layers on the substrate;
forming contacts in the interlayer dielectric layers via photolithography and etching processes; and
forming front metal layers on the substrate of the interlayer dielectric layers.

4. The method for manufacturing an IGBT device, according to claim 1, wherein the step of forming the collector region on the back of the substrate, further comprising:
forming the collector region on the back of the substrate, with ion implantation and anneal processes.

5. The method for manufacturing an IGBT device, according to claim 1, wherein the step of forming back metal layers on the back of the substrate, further comprising:
forming the back metal layers, via depositing the metal layer on the back of the substrate.

6-8. (canceled)
